(19) United States
(12) Patent Application Publication
(10) Pub. No.: US 2002/0199145 A1
(43) Pub. Date: Dec. 26, 2002

(54) Semiconductor integrated circuits built therein scan paths

(76) Inventor: Tatsunori Komoike, Tokyo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/137,450

(22) Filed: May 3, 2002

(30) Foreign Application Priority Data
Jun. 12, 2001 (JP) 2001-177554

(51) Int. Cl. G01R 31/28

(52) U.S. Cl. 714/729

(57) ABSTRACT

A semiconductor integrated circuit built therein scan paths comprising scan paths, connected to a combinational circuit block, each consisting of a plurality of SFFs, and a bidirectional pin, via which test patterns are not only input to the scan paths to apply the test patterns to the combinational circuit block when a control signal is set to an input mode but also output the results from the combinational circuit block. Control of the direction of a signal input to or output from the bidirectional pin is controlled by inputting the control signal from an external pin, or by adopting an internal circuit consisting of counters.

### BACKGROUND OF THE INVENTION

1. Field of the Invention

This invention relates to a semiconductor integrated circuit built therein scan paths, and more particularly to a semiconductor integrated circuit built therein scan paths on design for testability basis.

2. Description of Related Art

The operation will be described about a scan test for a typical semiconductor integrated circuit. Here, in the scan test on design for testability basis, a scan flip-flop (SFF) and a scan latch (SLt) have been used as well-known devices.

(1) First, When test patterns are input, a scan mode signal (SM signal) is set to an enable state to configure a shift register.

(2) The test patterns are input from a scan-in (SI pin) to a combinational circuit block in synchronization with a clock.

(3) Next, the SM signal is disabled and the results output from the combinational circuit block is latched by the scan latch (SLt) in synchronization with the next clock. The SM signal is enabled again to output the results outside of a tip by shift operations. Ordinarily, with execution of a shift operation the next test pattern is input.

(4) A scan operation is executed after repeating the above steps (1) to (3).

### First Prior Art

FIG. 5A is a schematic diagram showing a semiconductor integrated circuit built therein scan paths according to the first prior art. FIG. 5B is a detailed schematic diagram showing scan paths indicated by “X” is FIG. 5A.

As shown in FIG. 5A the semiconductor integrated circuit comprises a combinational circuit block 101 for connecting the scan paths, and scan flip-flops (SFFs) 11 to 19. The scan paths are established by SFFs. “S”. “V”, “W”, “Y” shown in FIG. 5B indicate interfaces with the combinational circuit block, which are used in an operation excepting a scan test.

The operation thereof will then be described.

(1) Test patterns are input from an SI pin by shifting by the number of SFFs 11 to 19, i.e. nine times.

(2) Inputting data to the SFF 19 of the last stage means that the test patterns are input to circuit elements to, i.e. the combinational circuit block 101 other than the SFFs 11 to 19.

(3) Upon the next clock is input, the results output from the combinational circuit block in step (2) are latched by the SFFs 11 to 19. A response from the combinational circuit block 101 will appear at an SFF of the next stage.

(4) The results are output from an SO pin by shifting by the number of SFF pins.

Since the scan paths are established by the SFFs 11 to 19, a few clock cycles are required: nine clock cycles for an initial test pattern input (shift-in) from the SI pin, one clock cycle for latching the results by the SFFs, nine clock cycles for outputting the results from the SO pin (shift-out), and for inputting the next test pattern (shift-in).

Accordingly, supposing that the subject testing circuit concerned shown in the first prior art are thoroughly tested only by inputting three test patterns to the scan paths, it will be required thirty-nine cycles (9+1+9+1+9+1+9) in total.

However, taking the above scan path configuration gets generally into difficulty that signal pins dedicated to a scan test only are an SM pin, the SI pin, and the SO pin, and therefore it would probably be hard to reduce the number of pins to less than three pins.

### Second Prior Art

FIG. 6 is a circuit diagram showing a semiconductor integrated circuit built therein scan paths devised to reduce the testing time according to the second prior art.

As shown in FIG. 6 the semiconductor integrated circuit comprises a combinational circuit block 101, scan flip-flops (SFFs) 11 to 19, and first and second scan path portions 13a, 13b, each of which establishes an overall scan path. Namely, a testing circuit is configured by dividing it into the first scan path portion consisting of SFFs 11 to 15 and the second scan path portion consisting of SFFs 16 to 19.

As can be seen from the above circuit configuration. The second prior art is differ from the first prior art in that the scan paths are properly divided into two scan path portions 13a, 13b, and in that test patterns are input from SI1 and SI2 pins and output from SO1 and SO2 pins.

The operation thereof will then be described.

A scan test operation such as a test pattern input and output of the results etc. shown in the second prior art are identical to those shown in the first prior art. Thus, shift operations require a few times than those of the first prior art and they are simultaneously executed, thus reducing in time required for the scan test.

In the above case, the testing time is determined based on the longest scan path. That is, five clock cycles are required for test patterns input (shift-in) to the first scan path portion 13a, one clock cycle for latching the results by the SFFs 11 to 15, five clock cycles for outputting the results (shift-out) and for inputting the next test pattern (shift-in). During the operation of the above scanpath 13a, the second scan path portion 13b consisting of the SFFs 16 to 19 are simultaneously tested. Hence, the semiconductor integrated circuit built therein scan paths in the second prior art requires 23 (5+1+5+1+5+1+5) clock cycles in total for testing, thus reducing the testing time as compared to the first prior art.

Similarly, the fewer the SFFs consisting of the scan paths utilize, the further reduction in the testing time will be attained. However, in the second prior art and their enhanced versions, dedicated SI and SO pins are needed for every setting of a plurality of scan path portions, and so attention should paid to the presence of trade-off lying between the above requirement and limitation put on the number of pins allowed for testing.

However, there has been a problem that reduction in the number of pins entails difficulty due to configurations of the conventional semiconductor integrated circuits built therein scan paths. Generally, signal pins for a scan test include an SM pin, the SI pin, and the SO pin.

Besides, there has been a problem that trade-off is present between the requirement that the SI and SO pins are dedicated to a plurality of scan paths, even if the scan paths are divided into two scan path portions in order to reduce the testing time, and limitation put on the number of pins allowed for testing.

### SUMMARY OF THE INVENTION

This invention has therefore been made to solve the above problems and an object thereof is to provide a semiconductor integrated circuit built therein scan paths, which has an ability ranked between the first and second prior arts, and which executes a scan test with reduced desired testing time and the number of pins to the minimum of a demand.

A semiconductor integrated circuit built therein scan paths according to the invention comprises scan paths, connected to a combinational circuit block, each having first and second scan path portions consisting of a plurality of scan flip-flops; a first bidirectional pin, via which test patterns are not only input to the first scan path portion to apply the test patterns to the first scan path portion when a control signal is set to an input mode but also output the results from the combinational circuit block to apply the test patterns to the combinational circuit block when the control signal is set to an output mode; a second bidirectional pin, via which the test patterns are not only input to the second scan path portion when a control signal is set to an input mode but also output the results from the combinational circuit block to apply the test patterns to the combinational circuit block when the control signal is set to an output mode.

Each of the first and second bidirectional pins comprise directional control means for changing the direction of a signal input to or output from the bidirectional pins depending on whether a control signal is set to an input mode or output mode.

A control signal input to the directional control means is supplied from the outside of a pin.

The directional control means comprises a tri-state buffer.

A semiconductor integrated circuit built therein scan paths according to the invention comprises scan paths, connected to a combinational circuit block, each having a bidirectional pin, via which test patterns are not only input to the scan pats to apply the test patterns to the combinational circuit block when a control signal is set to an input mode but also output the results from the combinational circuit block when the control signal is set to an output mode.

The direction of a signal input to or output from the bidirectional pin is set by inputting a control signal to a tip from an external pin. An internal circuit consisting of counters is adopted for directional control of the bidirectional pin.

The bidirectional pin comprises directional control means for changing the direction of a signal input to or output from the bidirectional pin.

The above and other objects and the attendant advantages of the invention will become readily apparent by referring to the following detailed description of the preferred embodiments when considered in conjunction with the accompanying drawings.

### BRIEF DESCRIPTION OF THE DRAWINGS

FIG. 1A is a schematic diagram showing a semiconductor integrated circuit built therein scan paths according to the first embodiment of the invention.

FIG. 1B is a detailed schematic diagram showing a bidirectional pin consisting of a tri-state buffer indicated by “A” in FIG. 1A.

FIG. 2 is a schematic diagram showing a semiconductor integrated circuit built therein scan paths according to the second embodiment of the invention.

FIG. 3 is a detailed schematic diagram showing scan pats consisting of SFFs indicated by “B” in FIG. 2.

FIG. 4A is a detailed schematic diagram showing a control circuit consisting of counters indicated by “C” in FIG. 2.

FIG. 4B is a timing chart of the control circuit.

FIG. 5A is a schematic diagram showing a semiconductor integrated circuit built therein scan paths according to the first prior art.

FIG. 5B is a detailed schematic diagram showing scan paths indicated by “X” in FIG. 5A.

FIG. 6 is a circuit diagram showing a semiconductor integrated circuit built therein scan paths according to the second prior art.

Throughout the figures, the same reference numerals, and characters, unless otherwise noted, are used to denote like features, elements, components, or portions of the illustrated embodiments.

### DETAILED DESCRIPTION OF THE PREFERRED EMBODIMENTS

Hereinafter, preferred embodiments of the invention will be described in detail with reference to the attached drawings.

### First Embodiment

The first embodiment is directed to a semiconductor integrated circuit in which scan pats are divided into first and second scan path portions where a bidirectional pin dedicated to both inputting and outputting of a signal are provided, respectively.

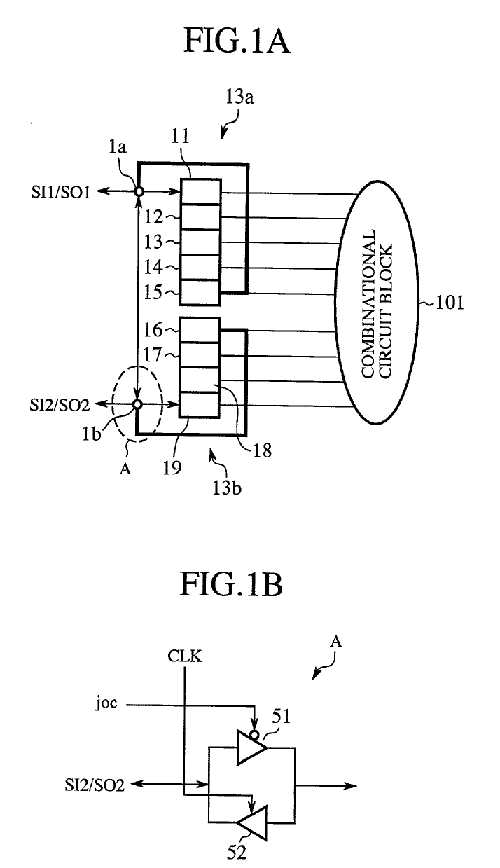

FIG. 1A is a schematic diagram showing a semiconductor integrated circuit built therein scan paths according to the first embodiment.

As shown in FIG. 1A the semiconductor integrated circuit comprises bidirectional pins (first and second bidirectional pins) 1a, 1b, scan flip-flops 11 to 19 (SFFs), a first scan path portion 13a, a second scan path portion 13b, tri-state buffers 51,52, and a combinational circuit block 101. The SFFs 11 to 19 are connected respectively to the combinational circuit block 101. A signal is input to (SI1,SI2) or output from (SO1,SO2) the bidirectional pins 1a,1b.

FIG. 1B is a schematic diagram showing a bidirectional pin consisting of a tri-state buffer indicated by “A” in FIG. 1A.

As shown in FIG. 1B the bidirectional pin 1b comprises a directional control circuit (directional control means) consisting of two tri-state buffers 51,52. A control signal for changing the inputting/outputting direction of a signal (hereinafter referred to as an ioc signal) is input to the tri-state buffer 51, a clock being input to the tri-state buffer 52. Only one ioc signal is at least needed for changing the direction of a signal input to or output from the bidirectional pins 1a,1b. Here, for example, an input mode (shift-in) is set when the ioc signal is “0”, while an output mode (shift-out) is set when the ioc signal is “1”.

Characteristics of the circuit configuration according to the first embodiment is not in that SI and SO pins are provided as an input only or an output only, but in that the SI and the SO pins are provided as bidirectional pins 1a, 1b (see a part indicated by “A” in FIG. 1A).

The operation thereof will then be described with reference to FIGS. 1A and 1B.

First, a scan mode signal (SM signal (not shown)) for starting a scan test is enabled and the ioc signal is set to an input mode (ioc signal=0) to input test patterns by shift operations. After having been inputted the test patterns to all the SFFs 11 to 19, the SM signal is disabled to input a clock for testing the combinational circuit block 101. Next, the SM signal is enabled again and the ioc signal is set to an output mode (ioc signal=1) to output the results by shift operations.

The semiconductor integrated circuit according to the first embodiment has a disadvantage that it cannot execute scan-in and scan-out operations simultaneously like the first and second prior arts. However, the semiconductor integrated circuit has an advantage that it shortens time required for a test, as compared to that of the first prior art, under the predetermined circumstances, as a consequence of reduction in the number of SFFs consisting of the scan paths, and that it requires a few number of test pins as compared to the second prior art.

As mentioned above, according to the first embodiment, since the scan paths are divided into the first and second scan path portions, the bidirectional pins 1a, 1b dedicated to both inputting and outputting of a signal being provided therewith, respectively, the pins dedicated to a scan test, such as the SI pin (input only) and SO pin (output only) are prevented their number from being increased, which is of a great advantage to designs and manufactures when they are applied to Very Large Scale Integrated circuits such as system LSIs, reducing testing time to a proper level.

### Second Embodiment

The second embodiment is directed to a semiconductor integrated circuit in which a bidirectional pin acts as both scan-in and scan-out, and in which a control circuit consisting of counters is adopted as an internal circuit for generating a control signal.

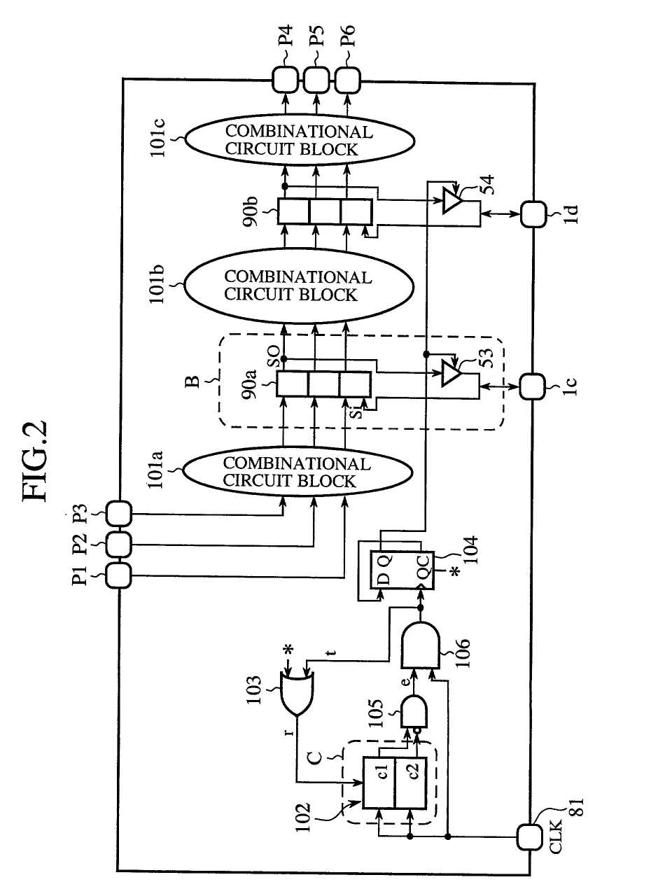

FIG. 2 is a schematic diagram showing a semiconductor integrated circuit built therein scan paths according to the second embodiment of the invention. As shown in FIG. 2 the semiconductor integrated circuit built therein scan paths comprises bidirectional pins 1c, 1d, combinational circuit blocks 101a to 101c, a clock (CLK) pin 81 for inputting an external clock, a counter 102, a flip-flop (FF) 104, AND gates 105, 106, an OR gate 103, tri-state buffers 53, 54, input pins P1 to P3, and output pins P4 to P6. In FIG. 2 thee combinational circuit blocks 101a to 101c and two scan paths 90a,90b are connected.

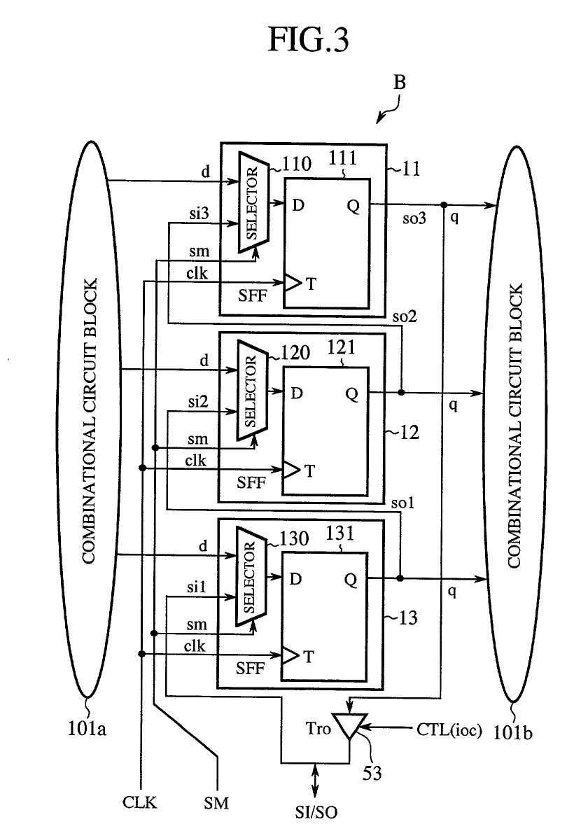

FIG. 3 is a detailed schematic diagram showing scan paths consisting of SFFs indicated by “B” in FIG. 2. As shown in FIG. 3 three scan flip-flops 11 to 13 are provided, which contain three flip-flops 111,121,131 and selectors 110,120,120. A CLK is input to T pins of the flip-flops 111,121,131, the SM signal to the selectors 110,120,130, and CTL signal to the tri-state buffer 53.

The scan-in or scan-out operation thereof using a bidirectional pin will then be described with reference FIGS. 2 and 3.

(1) At the bidirectional pin 1c side, for example, an SM signal is set to “H” and a CTL signal to “L” for activating (enable) the scan paths consisting of SFFs 11 to 13. In FIG. 3 the scan paths SI/SO→si1→so1→si2→so2→si3→so3 are thus established. Here, the SI/SO is coupled to the bidirectional pin 1c.

(2) Test patterns are input from the bidirectional pin 1c in synchronization with a clock input from the CLK pin 81. In this situation, data output from the so3 is not output from the tri-state buffer 53, as the tri-state buffer is in disabled state in which the CTL signal is set to “L”. Accordingly, no influence (change in value) is exerted on the input test patterns.

(3) Referring to FIGS. 2 and 3, the test patterns are input to all the SFFs 11 to 13 after three clocks are input as a shift register within the SFFs having three bits. The test patterns are applied to the combinational circuit block 101b or an output q of the SFFs 11 to 13. Then, a response from the combinational circuit block 101b appears at an input d of the SFF of the next stage (a response appears at the previous SFF 12 when a q is output from the SFF 13).

(4) The SM signal is set to “H” and the CTL signal to “L” or “H”, the input d is latched by the SFF in synchronization with a clock after the processing in step (3) has finished.

(5) The SM signal is set to “H” and the CTL signal to “H” to activate (enable) the scan paths consisting of the SFFs 11 to 13. In FIG. 3 scan paths so1→si2→so2→si3→so3→SI/SO are established.

(6) The results (obtained in step (4)) are output from the SI/SO pin in synchronization with a clock input from the CLK pin 81.

(7) The results are output directly to the shift registers at the same time, exerting no influence on the results.

In this way, the clock is supplied from the outside of a tip via the CLK pin 81. The test patterns are input or output via the bidirectional pins 1c, 1d, thus reducing increment in the number of pins to the minimum of a demand.

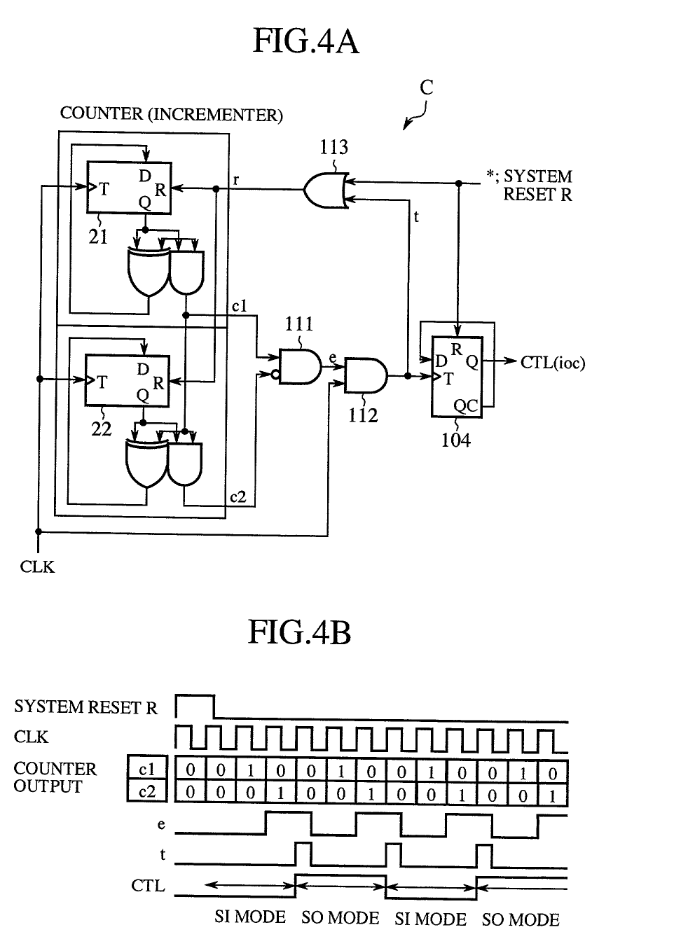

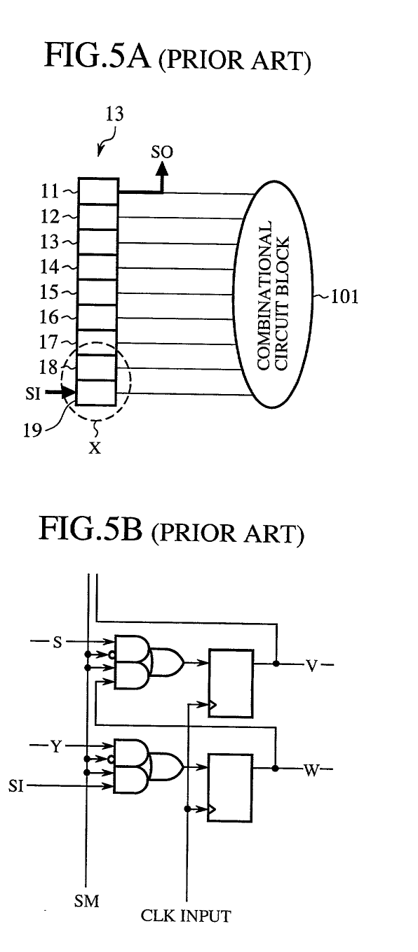

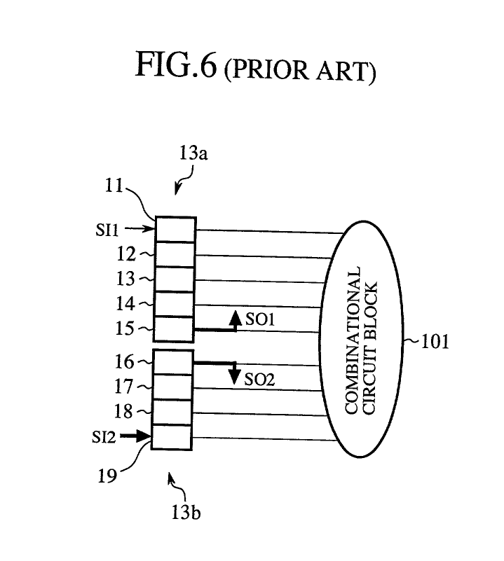

FIG. 4A is a detailed schematic diagram showing a control circuit consisting of counters indicated by “C” in FIG. 2. FIG. 4B is a timing chart of the control circuit.

While the above descriptions were given on the assumption that an ioc signal is supplied from the outside, it may be possible to configure a control circuit (see FIG. 4A) consisting of counters so as to reduce increment in the number of external pins, if there originally is any signal in an LSI which is available as a reset signal. Such an approach will be described later.

As shown in FIG. 2, a control circuit for example comprises counters 102 with a reset (clear) input, an OR gate 113 for generating a reset signal r from a reset signal of the LSI, or from a self-reset signal t of the control circuit, an AND gate 112 for generating a signal e which becomes valid when it is counted up by the counter 102 by the number of the SFF (or Slt) stages, a FF 104 for generating an ioc signal in synchronization with generation of the reset signal of the LSI or the self-reset signal. Here, assuming that the counter 42 is configured by a flip-flop (FF), an EXOR gate, and an AND gate as shown in FIG. 4A.

The scan-in or scan-out operation using a counter will then be described with reference to FIGS. 2 and 4.

Where the system reset signal r is a signal which is usually outputted when the LSI starts its operation. If there is no such a signal in the LSI, a replaceable signal is to be appropriately allocated.

(1) The contents of the counter (incrementer) 102 and FF 104 are once cleared when the system reset signal r is supplied thereto. In this situation, an output of “c1*c2” is “00”, the CTL signal is “0”. Thus, the output e of the AND gate 111 is “0”. As a result, a clock does not appear at the output t of the AND gate 112 and no operation will not be occurred in the FF 104.

(2) The counter 102 is cleared for starting an increment operation after the next clock is input.

(3) The output e of the counter 102 remains “n”, until its output will be “c1*c2”=01 (in “00, 10”). An operation of the FF 104 will not be taken place as in step (1).

(4) An output of the counter 102 becomes “c1*C2=10”, and the output e “1”. Further, an input of the next clock produces further increment of the counter 102, appearing at the node t. Hence, the FF 104 sets the CTL signal to “1”. At the same time, a change in the node t affects the reset signal r input to the counter 102 through the OR gate 113. Consequently, the counter 102 is cleared again and its output becomes “c1*C2=00”.

(5) Thereafter, the above steps (1) to (4) are repeated, i.e. an output of the counter takes bidirectional control of an I/O for the scan paths by repeating generations of the CTL signal=“0→1→0→1” as a unit of “c1*c2=00→10→01”.

Here, in FIGS. 2 and 3 the scan paths are established assuming the fact that the SFF has three bits, and so the incrementer is of two bits. In alternative scan path configuration, if it is established by a flip-flop SFF of (n) bits (n is a natural number), desired configuration will be attained by properly configuring a counter of n bits satisfying the relationship (k−1) 2≦n≦k2 (n is an integral number), an AND gate, and its inputs.

As noted above, according to the second embodiment, since in a scan test design, the SI pin (Scan-in) and SO pin (Scan-out) which are conventionally provided independently are replaced with a pin, i.e. the bidirectional pins 1c, 1d, and that inputting and outputting direction of the bidirectional pins are controlled by the control signal supplied from the outside, the number of test pins is prevented from being increased.

Also, since, if there is any signal which is available as a reset signal, the control circuit consisting of counters can be adopted as an internal circuit for generating the control signal (ioc signal) input via an external pin of the LSI to get directional control, the number of external pins is prevented from being increased.

### EXAMPLE

For demonstrating superiority of the invention to the first and second prior arts a comparison is made between the case where the number of SFF is set to x to establish a scan path (first prior art) and the case where a plurality of scan paths are established by z which consists of SFFs of a maximum of y (second prior art). The results of the comparison of time and number of pins dedicated to the scan test only are summarized as follows. Where “n” is the number of operations for a Scan-in (or Scan-out) required in the first prior art.

<Comparing Table>

| | | The Minimum Number of |
|---|---|---|
| Testing Time | | Pins for Test only |
| First Prior Art | 2x + (n − 1)x + n | 3(SM + SI + SO) |
| Second Prior Art | 2y + (n − 1)y + n | 1 + 2z(SM + zx(S1 + S0) |
| First Embodiment | 2ny + n | 1 + 1 + z(SM + ioc + zx(SI/SO) |
| Second Embodiment | 2ny + n | 1 + z(SM + zx(SI/SO)) |

Above comparison shows that a testing circuit using the semiconductor integrated circuit built therein scan paths according to the first and second embodiments takes shorter time than the first prior art under the restricted condition that y is less than one-half of x. Further, it shows that the first and second embodiments require a few number of pins than the second prior art, increment in the number of pins dedicated to a scan test only must be prevented at the cost of testing time, when necessary.

As mentioned above, the invention has the following features.

The invention prevents the number of pins dedicated to a scan test from being increased, thus reducing the testing time by dividing the scan paths into the first and second scan path portions. Therefore, the invention comprises scan paths, connected to a combinational circuit block, each having the first and second scan path portions consisting of a plurality of scan flip-flops, the first bidirectional pin, via which test patterns are not only input to the first scan path portion to apply the test patterns to the combinational circuit block when the control signal is set to an input mode but also output the results from the combinational circuit block when the control signal is set to an output mode, the second bidirectional pin, via which test patterns are not only input to the second scan path portion to apply the test patterns to the combinational circuit block when the control signal is set to an output mode but also output the results from the combinational circuit block when the control signal is set to an output mode.

The invention executes a scan-in or scan-out operation depending on whether a control signal is set to an input mode or output mode in a scan test. Therefore, each of first and second bidirectional pins comprise directional control means for changing the direction of a signal input to or output from the bidirectional pin depending on whether the control signal is set to an input mode or output mode.

The invention reduces the number of pins dedicated to a scan test for receiving a control signal to the minimum of a demand. Therefore, the control signal input to the directional control means is supplied from the outside of a tip.

The invention takes directional control of the bidirectional pin in a less abstract manner. Therefore, directional control means comprises a tri-state buffer.

The invention prevents the number of pins dedicated to a scan test from being increased, thus reducing the testing time by dividing the scan paths into the first and second scan path portions. Therefore, the invention comprises scan paths, connected to the combinational circuit block, each consisting of a plurality of scan flip-flops, the bidirectional pin, via which test patterns are not only input to the scan paths to apply the test patterns to the combinational circuit block when a control signal is set to an input mode but also output the results from the combinational circuit block when the control signal is set to an output mode.

The invention reduces increment in the number of pins dedicated to a scan test for receiving a control signal to the minimum of a demand. Therefore, directional control of the bidirectional pins is taken by inputting the control signal to a pin from the outside.

The invention generates a control signal without adding any external pin. Therefore, directional control of the bidirectional pin is taken by the internal circuit consisting of counters.

The invention executes a scan-in or scan-out operation depending on whether a control signal is set to an input mode or output mode in a scan test. Therefore, the bidirectional pin comprises directional control means for changing the direction of a signal input thereto or output therefrom.

While, in the above prior arts and preferred embodiments of the invention, very small circuit configuration is given as an example for brevity, it should be understood by those skilled in the art that various modifications and changes may be made without departing from the sprit and scope of the invention. For example, very large integrated circuits such as system LSIs may be taken in place of the above small circuit. Even in this case, the same design philosophies are held and equivalent effects are still obtained.

Also, it should be noted that the invention meets all the objects mentioned above and also has the advantages of wide commercial utility, and that the invention has been set forth for purposes of illustration only and not of limitation. That is, the invention is limited only by the following claims which follow. Consequently, reference should be made to the following claims in determining the full scope of the invention.

What is claimed is:

1. A semiconductor integrated circuit built therein scan paths comprising:
a combinational circuit block;
scan paths, connected to said combinational circuit block, each having first and second path portions consisting of a plurality of scan flip-flops;
a first bidirectional pin, via which test patterns are not only input to said first scan path portion to apply the test patterns to said combinational circuit block when a control signal is set to an input mode but also output the results from said combinational circuit block when the control signal is set to an output mode; and
a second bidirectional pin, via which test patterns are not only input to said second scan path portion to apply the test patterns to said combinational circuit block when a control signal is set to an input mode but also output the results to said combinational circuit block when the control signal is set to an output mode.

2. The semiconductor integrated circuit built therein scan paths according to claim 1, wherein each of said first and second bidirectional pins comprise directional control means for changing the direction of a signal input to or output from said first and second bidirectional pins depending on whether the control signal is set to an input mode or output mode.

3. The semiconductor integrated circuit built therein scan paths according to claim 2, wherein the control signal input to said directional control means is supplied from the outside of a tip.

4. The semiconductor integrated circuit built therein scan paths according to claim 2, wherein said directional control means comprises a tri-state buffer.

5. The semiconductor integrated circuit built therein scan paths comprising:
a combinational circuit block;
scan paths, connected to said combinational circuit block, each consisting of a plurality of scan flip-flops; and
a bidirectional pin, via which test patterns are not only input to said scan paths when a control signal is set to an input mode but also output the results from said combinational circuit block when the control signal is set to an output mode.

6. The semiconductor integrated circuit built therein scan paths according to claim 5, wherein the direction of a signal input to or output from said bidirectional pin is set by inputting the control signal to the tip from an external pin.

7. The semiconductor integrated circuit built therein scan paths according to claim 5, wherein an internal circuit consisting of counters is adopted for directional control of said bidirectional pin.

8. The semiconductor integrated circuit built therein scan paths according to claim 6, wherein said bidirectional pin comprises directional control means for changing the direction of a signal input to or output from said bidirectional pin.
